(19) United States
(12) Patent Application Publication
(10) Pub. No.: US 2025/0392275 A1
(43) Pub. Date: Dec. 25, 2025

(54) POWER AMPLIFIER

(71) Applicant: Sumitomo Electric Industries, Ltd., Osaka (JP)

(72) Inventor: Hirotaka ASAMI, Osaka (JP)

(73) Assignee: Sumitomo Electric Industries, Ltd., Osaka (JP)

(21) Appl. No.: 19/243,058

(22) Filed: Jun. 19, 2025

(30) Foreign Application Priority Data
Jun. 21, 2024 (JP) 2024-100422

(51) Int. Cl. H03F 3/60; H03F 1/56; H03F 3/24

(52) U.S. Cl. CPC H03F 3/602; H03F 1/56; H03F 3/245; H03F 2200/198

(57) ABSTRACT

A power amplifier of the present disclosure includes a balanced type amplifier and a control amplifier. The balanced type amplifier includes a first amplifier and a second amplifier to amplify input power. The control amplifier forms a load modulated balanced amplifier together with the balanced type amplifier, and supplies a control signal including a harmonic component of the input power to the balanced type amplifier. The control amplifier is a Class-AB amplifier or a Class-B amplifier. Each of the first amplifier and the second amplifier is a Class-C amplifier.

### CROSS REFERENCE TO RELATED APPLICATIONS

This application claims priority based on Japanese Patent Application No. 2024-100422 filed on Jun. 21, 2024, and the entire contents of the Japanese patent application are incorporated herein by reference.

### TECHNICAL FIELD

The present disclosure relates to a power amplifier.

### BACKGROUND

A load modulated balanced amplifier (LMBA) is disclosed in each of U.S. Patent Application Publication No. 2018/0205348 specification (Patent literature 1), Japanese National Patent Publication No. 2022-506367 (Patent literature 2), and U.S. Patent Application Publication No. 2022/0255506 specification (Patent literature 3).
Non-patent literature 1: Jingzhou Pang, Yue Li, Meng Li, Yikang Zhang, Xin Yu Zhou, Zhijiang Dai and Anding Zhu, Analysis and Design of Highly Efficient Wideband RF-Input Sequential Load Modulated Balanced Power Amplifier, IEEE Transactions on Microwave Theory and Techniques, Vol. 68, No. 5, May 2020.

### SUMMARY

A power amplifier of the present disclosure includes a balanced type amplifier and a control amplifier. The balanced type amplifier is configured to amplify an input power and includes a first amplifier and a second amplifier. The control amplifier is configured to form a load modulated balanced amplifier together with the balanced type amplifier and supplies a control signal including a harmonic component of the input power to the balanced type amplifier. The control amplifier is a Class-AB amplifier or a Class-B amplifier. Each of the first amplifier and the second amplifier is a Class-C amplifier.

### BRIEF DESCRIPTION OF THE DRAWINGS

FIG. 1 is a block diagram showing an application example of a power amplifier according to a first embodiment.

FIG. 2 is a circuit block diagram showing a basic configuration of a power amplifier according to a first embodiment.

FIG. 3 is a circuit block diagram showing an implementation example of a power amplifier according to a first embodiment.

FIG. 4 is a diagram showing a voltage waveform and a current waveform for explaining power consumption of a transistor.

FIG. 5 is a diagram showing a voltage waveform and a current waveform in an ideal Class-F amplifier.

FIG. 6 is a circuit block diagram showing a configuration of a power amplifier according to a first comparative example.

FIG. 7 is a circuit block diagram showing a configuration of a power amplifier according to a second comparative example.

FIG. 8 is a diagram for comparing power efficiency of a power amplifier between the embodiment and a second comparative example.

FIG. 9 is a Smith chart showing an example of a simulation result of an impedance of a balanced type amplifier when harmonic injection is not performed.

FIG. 10 is a Smith chart showing an example of a simulation result of an impedance of a balanced type amplifier when harmonic injection is performed.

FIG. 11 is a diagram showing an example of a simulation result of power efficiency of each amplifier forming a balanced type amplifier in a first embodiment.

FIG. 12 is a diagram showing an example of a simulation result of power efficiency of the entire balanced type amplifier in a first embodiment.

FIG. 13 is a circuit block diagram showing an example of a configuration of a power amplifier according a second embodiment.

FIG. 14 is a Smith chart showing an example of a simulation result of an impedance of a balanced type amplifier when harmonic injection is performed with a harmonic control installed.

FIG. 15 is a diagram showing an example of a simulation result of power efficiency of each amplifier forming a balanced type amplifier in a second embodiment.

FIG. 16 is a diagram summarizing simulation results of power efficiency of balanced power amplifiers in a first embodiment and a second embodiment.

### DETAILED DESCRIPTION

To reduce power consumption of a power amplifier, there is always a demand for improving power efficiency of the power amplifier. In an application such as a base station in which a large number of power amplifiers are used, a demand for improvement in power efficiency of the power amplifier is particularly significant.

One of the objectives of the present disclosure is to improve power efficiency of a power amplifier.

### Description of Embodiments of Present Disclosure

First, embodiments of the present disclosure will be listed and described.

(1) A power amplifier according to the present disclosure includes
a balanced type amplifier configured to amplify an input power and including a first amplifier and
a second amplifier, and
a control amplifier configured to form a load modulated balanced amplifier together with the balanced type amplifier and supply a control signal including a harmonic component of the input power to the balanced type amplifier.
The control amplifier is a Class-AB amplifier or a Class-B amplifier, and
each of the first amplifier and the second amplifier is a Class-C amplifier.

In the above configuration, the operation of the control amplifier, which is a Class-AB amplifier or a Class-B amplifier, is started first, and then the operation of the first amplifier and the second amplifier (balanced type amplifier), which are each Class-C amplifiers, is started. When the control amplifier reaches a saturation state, the harmonic component included in the control signal increases. Thus, when the balanced type amplifier is operated, a sufficient harmonic component is always injected into the balanced type amplifier. Thus, according to the above configuration, the power efficiency of the power amplifier can be improved.

(2) In the above (1),
a transmission line for the control signal from the control amplifier to the balanced type amplifier may include no harmonic control, and
the balanced type amplifier may include no harmonic control.

In the above configuration, the harmonic control capable of removing the harmonic component is not provided in the transmission line for the control signal or the balanced type amplifier. Thus, according to the above configuration, a control signal including a sufficient harmonic component can be supplied from the control amplifier to the balanced type amplifier.

(3) In the above (1) or (2),
the power amplifier may further include a harmonic control configured to reflect a harmonic component included in an output power of the balanced type amplifier to the balanced type amplifier.

In the above configuration, the harmonic component included in the output power of the balanced type amplifier is reflected to the balanced type amplifier. Thus, the phases of the reflected waves of the harmonic components are aligned and the amount of reflection of the harmonic components increases, so that the effect of improving the power efficiency of the power amplifier is enhanced. Thus, according to the above configuration, the power efficiency of the power amplifier can be further improved.

(4) In any one of the above (1) to (3),
the power amplifier may further include a matching network configured to match an impedance of
the control amplifier with an impedance of the balanced type amplifier.

According to the above configuration, the impedance of the control amplifier and the impedance of the balanced type amplifier are matched, and thus the power efficiency of the power amplifier can be further improved.

(5) In the above (1),
the balanced type amplifier may further include
a distributor configured to distribute the input power to the first amplifier and the second amplifier, and
a combiner configured to combine a power amplified by the first amplifier with a power amplified by the second amplifier. The distributor may be a directional coupler with a phase difference of 90°, and
the distributor may include a first port configured to receive the input power,
a second port to which a terminator is coupled,
a third port coupled to an input node of the first amplifier, and
a fourth port coupled to an input node of the second amplifier.
The combiner may be a directional coupler with a phase difference of 90°, and
the combiner may include a fifth port coupled to an output node of the first amplifier,
a sixth port coupled to an output node of the second amplifier,
a seventh port configured to receive the control signal, and
an eighth port configured to output the combined power.

According to the above configuration, the balanced type amplifier capable of improving the power efficiency can be appropriately configured.

(6) In the above (5),
a transmission line between the control amplifier and the seventh port may include no harmonic control, and
the balanced type amplifier may include no harmonic control between the output node of the first amplifier and the fifth port, and without including a harmonic control between the output node of the second amplifier and the sixth port.

In the above configuration, the harmonic control capable of removing the harmonic component is not provided in the transmission line for the control signal or the balanced type amplifier. Thus, according to the above configuration, a control signal including a sufficient harmonic component can be supplied from the control amplifier to the balanced type amplifier.

(7) In the above (5) or (6),
the power amplifier may further include a harmonic control coupled to the eighth port.

In the above configuration, the harmonic component included in the output power of the balanced type amplifier is reflected to the balanced type amplifier. Thus, the phases of the reflected waves of the harmonic components are aligned and the amount of reflection of the harmonic components increases, so that the effect of improving the power efficiency of the power amplifier is enhanced. Thus, according to the above configuration, the power efficiency of the power amplifier can be further improved.

(8) In any one of the above (5) to (7),
the power amplifier may further include a matching network coupled between the control amplifier and the seventh port.

According to the above configuration, the impedance of the control amplifier and the impedance of the balanced type amplifier are matched, and thus the power efficiency of the power amplifier can be further improved.

(9) In any one of the above (1) to (8),
the power amplifier may further include a divider configured to divide an original signal to provide a part of the original signal to the balanced type amplifier as the input power and another part of the original signal to the control amplifier.

According to the above configuration, the balanced type amplifier and the control amplifier are operated by a single signal, and thus the control signal can be generated with a simple circuit configuration.

(10) A power amplifier according to the present disclosure includes
a first amplifier and a second amplifier that each form a part of a balanced type amplifier configured to amplify an input power, and
a control amplifier configured to form a load modulated balanced amplifier together with the balanced type amplifier and supply a control signal including a harmonic component of the input power to the balanced type amplifier.
The control amplifier is a Class-AB amplifier or a Class-B amplifier, and
each of the first amplifier and the second amplifier is a Class-C amplifier.

In the above configuration, the operation of the control amplifier, which is a Class-AB amplifier or a Class-B amplifier, is started first, and then the operation of the first amplifier and the second amplifier, which are each Class-C amplifiers, is started. When the control amplifier reaches a saturation state, the harmonic component included in the control signal increases. Thus, when the first amplifier and the second amplifier are operated, a sufficient harmonic component is always injected into the balanced type amplifier. Thus, according to the above configuration, the power efficiency of the power amplifier can be improved.

### Details of Embodiments of Present Disclosure

Next, embodiments of the present disclosure will be described in detail with reference to the drawings. In the drawings, the same or corresponding parts are denoted by the same reference numerals, and the description thereof will not be repeated. At least some of the embodiments described below may be arbitrarily combined.

### Explanation of Terms

In the present disclosure and embodiments thereof, the term “high-frequency” means electromagnetic waves in the MHz band or GHz band (a band of frequencies equal to or more than 1 MHz and less than 1 THz). The high-frequency includes a microwave. The “microwave” means electromagnetic waves in a band equal to or more than 300 MHz and less than 300 GHz.

In the present disclosure and embodiments thereof, the “power efficiency” of the power amplifier means a ratio of output power from a power amplifier to supply power from a DC power supply to the power amplifier (power efficiency=output power/supply power).

### First Embodiment

### Overall Configuration

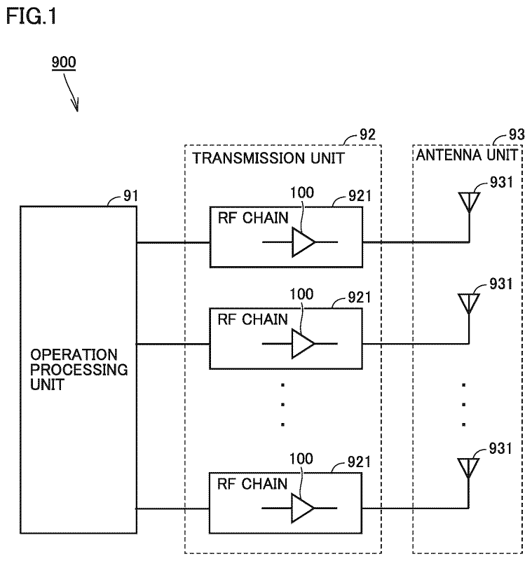

FIG. 1 is a block diagram showing an application example of a power amplifier according to a first embodiment. In this example, the power amplifier is applied to a base station. A base station 900 is, for example, a massive multiple input multiple output (massive MIMO) base station used in the fifth generation mobile communication system (5G). The base station 900 includes an operation processing unit 91, a transmission unit 92, and an antenna unit 93.

The operation processing unit 91 performs digital signal processing (baseband processing and the like) of information transmitted from the base station 900 at the time of communication between the base station 900 and a communication device (not shown).

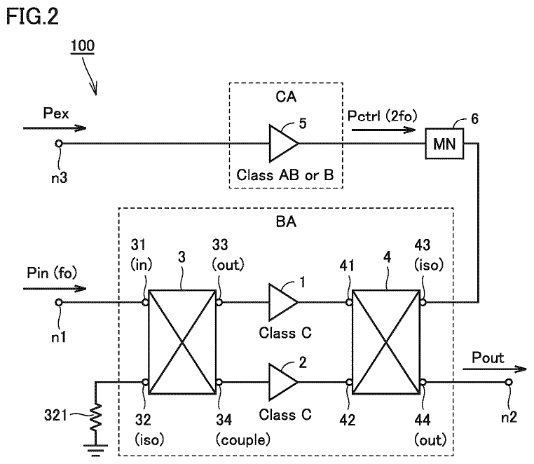

The transmission unit 92 includes a plurality of radio frequency (RF) chains 921. Each of the plurality of RF chains 921 includes a power amplifier 100 in addition to a filter, a switch, a mixer, a D/A converter, and the like (none of which are shown). The configuration of the power amplifier 100 will be described in detail with reference to FIG. 2 and subsequent drawings.

The antenna unit 93 includes a plurality of antennas 931. The plurality of antennas 931 are connected to the plurality of RF chains 921, respectively.

The base station 900 is merely an example of the application of the power amplifier 100, and the application of the power amplifier according to the present disclosure is not limited thereto. The power amplifier according to the present disclosure may be applied to various devices (such as a portable terminal) used in a mobile communication system, for example.

### <<Configuration of Power Amplifier>>

FIG. 2 is a circuit block diagram showing a basic configuration of the power amplifier according to the first embodiment. The power amplifier 100 is a load modulated balanced amplifier. The power amplifier 100 includes a first amplifier 1, a second amplifier 2, a distributor 3, a combiner 4, a control amplifier (CA) 5, and a matching network (MN) 6.

Each of the first amplifier 1 and the second amplifier 2 is a Class-C amplifier. The first amplifier 1 and the second amplifier 2 have the same size. The first amplifier 1 and the second amplifier 2 are implemented by, for example, gallium nitride (GaN) high electron mobility transistors (HEMTs). However, the implementation of each of amplifiers is not limited to this. The first amplifier 1 and the second amplifier 2 may be implemented by an insulated gate bipolar transistor (IGBT) or may be implemented by a metal-oxide-semiconductor field-effect transistor (MOSFET) (for example, a laterally diffused MOSFET (LDMOSFET)). The material of each of the first amplifier 1 and the second amplifier 2 may be silicon (Si), silicon carbide (SiC), or the like.

The first amplifier 1 and the second amplifier 2 form a balanced type amplifier BA together with the distributor 3 and the combiner 4. The balanced type amplifier BA receives a high-frequency (typically, a microwave) input power Pin from a node n1. A frequency of the input power Pin is denoted by f₀. The balanced type amplifier BA generates an output power Pout by amplifying the input power Pin, and supplies the output power Pout to a load (not shown) connected to a node n2.

The distributor 3 distributes the input power Pin to the first amplifier 1 and the second amplifier 2. The combiner 4 combines a power amplified by the first amplifier 1 with a power amplified by the second amplifier 2. More specifically, each of the distributor 3 and the combiner 4 is a directional coupler with a phase difference of 90°. The degree of coupling of the distributor 3 and the combiner 4 is, for example, 3 dB.

The distributor 3 includes a first port 31, a second port 32, a third port 33, and a fourth port 34. The first port 31 is an input port and receives the input power Pin from a power source (not shown) via the node n1. The second port 32 is an isolation port and is terminated by a terminator 321. The third port 33 is an output port and outputs power having an amplitude that is half the input power Pin and having a phase delay of 90° with respect to the input power Pin. The third port 33 is connected to an input node of the first amplifier 1. The fourth port 34 is a coupled port and outputs power having an amplitude that is half the input power Pin and having a phase delay of 180° with respect to the input power Pin. The fourth port 34 is connected to an input node of the second amplifier 2.

The combiner 4 includes a first port 41, a second port 42, a third port 43, and a fourth port 44. The first port 41 is connected to an output node of the first amplifier 1. The second port 42 is connected to an output node of the second amplifier 2. The third port 43 functions as an isolation port. The fourth port 44 functions as an output port.

More specifically, the first port 41 of the combiner 4 receives the power amplified by the first amplifier 1. This power has a phase delay of 90° at the time of being output from the third port 33 of the distributor 3. A phase delay of 90° is added to the power component transmitted from the first port 41 to the third port 43 of the combiner 4. A phase delay of 180° is added to the power component transmitted from the first port 41 to the fourth port 44 of the combiner 4.

The second port 42 of the combiner 4 receives the power amplified by the second amplifier 2. This power has a phase delay of 180° at the time of being output from the fourth port 34 of the distributor 3. A phase delay of 180° is added to the power component transmitted from the second port 42 to the third port 43 of the combiner 4. A phase delay of 90° is added to the power component transmitted from the second port 42 to the fourth port 44 of the combiner 4.

The power component transmitted from the first port 41 to the third port 43 of the combiner 4 and the power component transmitted from the second port 42 to the third port 43 have the same amplitude and opposite phases. Since these two power components cancel each other, no power is output from the third port 43.

The power component transmitted from the first port 41 to the fourth port 44 of the combiner 4 and the power component transmitted from the second port 42 to the fourth port 44 have the same amplitude and the same phase. Thus, the power in which these two power components are constructive is output from the fourth port 44 as the output power Pout. The output power Pout is supplied to the load (not shown) via the node n2.

The first port 31 to the fourth port 34 of the distributor 3 correspond to the “first port” to the “fourth port” according to the present disclosure, respectively. The first port 41 to the fourth port 44 of the combiner 4 correspond to the “fifth port” to the “eighth port” of the present disclosure, respectively.

A control amplifier 5 is a Class-AB amplifier or a Class-B amplifier. The control amplifier 5 is implemented by, for example, a GaN HEMT, similarly to the first amplifier 1 and the second amplifier 2. However, the control amplifier 5 may be implemented by an IGBT of Si or SiC, or may be implemented by a MOSFET of Si or SiC.

In this example, an external signal Pex is supplied from a signal source (not shown) to the control amplifier 5 via a node n3. The control amplifier 5 generates a control signal Pctrl from the external signal Pex. The control signal Pctrl in the embodiment includes a harmonic component (harmonic component equal to or more than the frequency 2f₀) of the input power Pin to the balanced type amplifier BA. The control amplifier 5 load modulates the balanced type amplifier BA by suppling the control signal Pctrl to the third port 43 of the combiner 4 via a matching network 6. Hereinafter, this load modulation method is also referred to as “harmonic injection”. The harmonic injection improves the power efficiency of the balanced type amplifier BA. The principle of the harmonic injection will be described later.

The matching network 6 is coupled between the control amplifier 5 and the third port 43 of the combiner 4. The matching network 6 matches impedance between the output node of the control amplifier 5 and the third port 43 of the combiner 4. By providing the matching network 6, the power efficiency of the power amplifier 100 can be further improved.

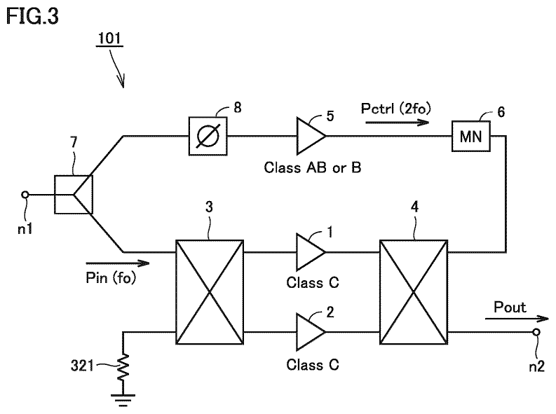

FIG. 3 is a circuit block diagram showing an implementation example of the power amplifier according to the first embodiment. To avoid the space in a drawing from becoming complicated, the ports of the distributor 3 and the combiner 4 are not shown in FIG. 3 and subsequent drawings. Hereinafter, the third port 43 of the combiner 4 is also referred to as an “isolation port”, and the fourth port 44 of the combiner 4 is also referred to as an “output port”.

A power amplifier 101 shown in FIG. 3 is different from the power amplifier 100 (see FIG. 2) in that it further includes a divider 7 and a phase shifter 8.

When the divider 7 receives an original signal from the node n1, the divider 7 divides the original signal. A part of the original signal is supplied to the first port 31 of the distributor 3 as the input power Pin. Another part of the original signal is supplied to the control amplifier 5 via the phase shifter 8.

The phase shifter 8 delays the phase of the signal supplied from the divider 7 to the control amplifier 5. The phase delay amount of the phase shifter 8 is adjusted so that the phase of the power passing through the combiner 4 and the phase of the control signal Pctrl supplied from the control amplifier 5 to the isolation port of the combiner 4 are aligned at the isolation port of the combiner 4.

The other configurations of the power amplifier 101 are the same as the corresponding configurations of the power amplifier 100, and thus the description thereof will not be repeated. According to the power amplifier 101, a signal source for supplying the external signal Pex (see FIG. 2) can be omitted.

### <<Principle of Harmonic Injection>>

There is always a demand for improving power efficiency of the power amplifier. As will be explained below, the improvement in power efficiency of the power amplifier is achieved by a reduction in power consumption of the power amplifier.

According to the distortion AC theory, a voltage (typically, the drain voltage of a transistor forming a power amplifier) V(t) of a transistor is expressed by the following equation (1). A current (drain current) I(t) flowing through the transistor is expressed by the following equation (2). t represents elapsed time. ω represents an angular frequency (center frequency). n is a natural number representing the order of the frequency component. φn represents a phase difference of the n-th order frequency component with respect to the fundamental wave. θn represents a phase difference of the n-th order voltage with respect to the n-th order current.

$$\begin{matrix}[ Math 1 ] & \\ V ( t ) = {V}_{D C} + \sqrt{2} {V}_{1} sin ( ω t + {φ}_{1} + {θ}_{1} ) + {\sum }_{n = 2} \sqrt{2} {V}_{n} sin ( n ω t + {φ}_{n} + {θ}_{n} ) & ( 1 )\end{matrix}$$

$$I ( t ) = {I}_{D C} + \sqrt{2} {I}_{1} sin ( ω t + {φ}_{1} ) + {\sum }_{n = 2} \sqrt{2} {I}_{n} sin ( n ω t + {φ}_{n} ) \qquad ( 2 )$$

The equation (1) represents that the voltage V(t) of the transistor includes a direct current component (first term on the right side), a fundamental wave component (second term on the right side) of n=1, and a harmonic component (third term on the right side) of n≥2. The same applies to the current expressed by equation (2).

A power consumption (time average value in the period T) Pave of the transistor is calculated from equation (1) and equation (2) as in equation (3) below.

$$\begin{matrix}[ Math 2 ] & \\ {P}_{a v e} = \frac{1}{T} {\int }_{0}^{T} V ( t ) \cdot I ( T ) dt = {V}_{D C} {I}_{D C} + {V}_{1} {I}_{1} cos {θ}_{1} + {\sum }_{n = 2} {V}_{n} {I}_{n} cos {θ}_{n} & ( 3 )\end{matrix}$$

It is understood from equation (3) that the power consumption Pave of the transistor also includes a DC component (the first term on the right side), a fundamental wave component (the second term on the right side) of n=1, and a harmonic component (the third term on the right side) of n≥2.

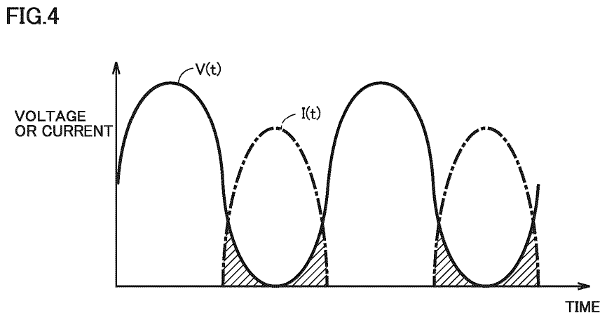

FIG. 4 is a diagram showing a voltage waveform and a current waveform for explaining power consumption of a transistor. The horizontal axis represents elapsed time. The vertical axis represents the magnitude of the voltage or current supplied to the transistor.

As described above, the power consumption Pave of the transistor may be reduced to improve the power efficiency of the transistor, and the power consumption Pave is expressed by the area of the region (shown by hatching) where the voltage waveform and the current waveform overlap each other in the drawing. As the area of the region is smaller, the power consumption Pave is smaller, and thus the power efficiency is improved. For example, in an ideal Class-F amplifier, the voltage waveform and the current waveform do not overlap at all, and 100% power efficiency can be achieved.

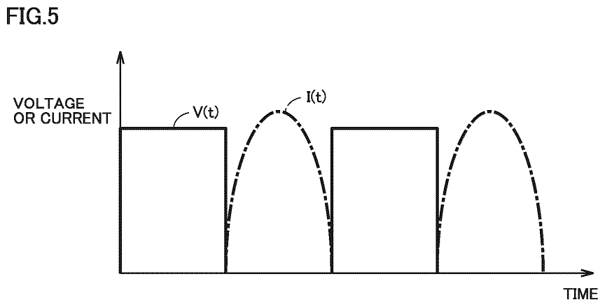

FIG. 5 is a diagram showing a voltage waveform and a current waveform in an ideal Class-F amplifier. The voltage waveform and the current waveform shown in FIG. 5 correspond to a situation where the first term and the second term on the right side are balanced and the third term on the right side is zero in the above equation (3). The first term and the second term on the right side being balanced means that the two terms are equal in magnitude and opposite in sign. The third term on the right side being zero means that the phase of the voltage waveform and the phase of the current waveform of the same order are shifted by 90° (θn=π/2) for all the orders n, or that at least one of the voltage V(t) or the current I(t) is always zero.

The voltage waveform and the current waveform shown in FIG. 5 are expressed by the following equations (4) and (5), respectively, by Fourier series expansion. The term of the order n (coefficient of ω) of 2 or more in the right side of equation (4) and equation (5) represents a harmonic component.

$$\begin{matrix}[ Math 2 ] & \\ V ( t ) = {V}_{max} ( \frac{1}{2} \cdot \frac{2}{π} cos ω t + \frac{2}{2 π} cos 3 ω t - \frac{2}{5} cos 5 ω t + … ) & ( 4 )\end{matrix}$$

$$I ( t ) = \frac{{I}_{max}}{π} ( 1 \cdot \frac{π}{2} cos ω t + \frac{2}{3} cos 2 ω t - \frac{2}{15} cos 4 ω t + … ) \qquad ( 5 )$$

Since the distorted waveform includes harmonics, a harmonic component is necessary to reduce the power consumption Pave of the power amplifier from equations (3), (4), and (5). In the embodiment, the voltage waveform and the current waveform are shaped by injecting the harmonic component from the control amplifier 5 to the balanced type amplifier BA (more specifically, the isolation port of the combiner 4). As a result, the harmonic component (the third term on the right side) of the equation (3) becomes small, and the voltage waveform and the current waveform as shown in FIG. 4 approach the waveforms shown in FIG. 5. As a result, the power efficiency of the balanced type amplifier BA can be improved.

### First Comparative Example

A configuration for injecting a harmonic component from the control amplifier 5 to the balanced type amplifier BA will be described in comparison with a power amplifier according to a first comparative example.

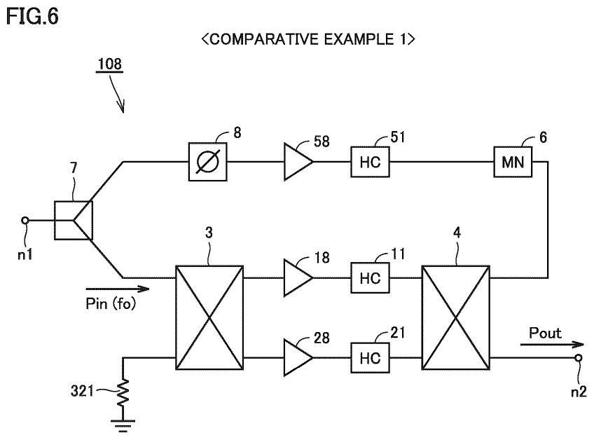

FIG. 6 is a circuit block diagram showing a configuration of a power amplifier according to the first comparative example. A power amplifier 108 according to the first comparative example is different from the power amplifier 101 according to the first embodiment (see FIG. 3) in the following two points. First, the power amplifier 108 includes a first amplifier 18, a second amplifier 28, and a control amplifier 58 instead of the first amplifier 1, the second amplifier 2, and the control amplifier 5. The operation classes of these amplifiers are not limited.

Second, the power amplifier 108 further includes a harmonic control (HC) 11, a harmonic control 21, and a harmonic control 51.

The harmonic control 11 is coupled between an output node of the first amplifier 18 and the first port 41 of the combiner 4. The harmonic control 11 includes a harmonic filter and a phase adjustment circuit (both not shown), and is configured to reflect a harmonic component included in the power amplified by the first amplifier 18 to the output node of the first amplifier 18. As a specific example, the harmonic control 11 is configured such that the output node of the first amplifier 18 is short-circuited or open-circuited for even-order harmonic components and is short-circuited or open-circuited for odd-order harmonic components. Since the harmonic component is reflected from the harmonic control 11, the harmonic component hardly propagates to the subsequent stages of the harmonic control 11.

The harmonic control 21 is coupled between an output node of the second amplifier 28 and the second port 42 of the combiner 4. The harmonic control 21 is configured to reflect a harmonic component included in the power amplified by the second amplifier 28 to the output node of the second amplifier 28, similarly to the harmonic control 11.

The harmonic control 51 is coupled between an output node of the control amplifier 58 and the matching network 6. The harmonic control 51 is configured to reflect a harmonic component included in the control signal Pctrl output from the control amplifier 58 to the output node of the control amplifier 58.

By installing the harmonic control 11, the power consumption of the first amplifier 18 is reduced, and the power efficiency of the first amplifier 18 is improved. The same applies to the harmonic control 21. In addition, the harmonic control 51 is installed, so that the power consumption of the control amplifier 58 is reduced and the power efficiency of the control amplifier 58 is improved. As described above, in the first comparative example, the first amplifier 18, the second amplifier 28, and the control amplifier 58 are merely improved in power efficiency individually by the corresponding harmonic controls. Harmonic components generated in each amplifier are removed by reflection. The harmonic output from one amplifier is not used for the purpose of improving the power efficiency of another amplifier. In particular, the harmonic component included in the control signal Pctrl from the control amplifier 58 is removed by the harmonic control 51, and thus is not injected (supplied) to the balanced type amplifier.

As described above, the power amplifier 101 according to the first embodiment is different from the power amplifier 108 according to the first comparative example in that the transmission line for the control signal Pctrl from the control amplifier 5 to the balanced type amplifier BA includes no harmonic control. The balanced type amplifier BA of the power amplifier 101 also includes no harmonic control.

In the circuit block diagram showing the circuit configuration of the power amplifier, the harmonic control may be omitted in some cases. For example, although the harmonic control is not shown in the circuit block diagram shown in FIG. 1 of the non-patent literature 1, the harmonic control is provided at the position shown in FIG. 6 of the present disclosure.

### Second Comparative Example

The balanced type amplifier BA (each of the first amplifier 1 and the second amplifier 2) in the first embodiment is a Class-C amplifier, and the control amplifier 5 is a Class-AB amplifier or a Class-B amplifier. The advantage of adopting such operation classes of the amplifiers will be described in comparison with a power amplifier according to a second comparative example.

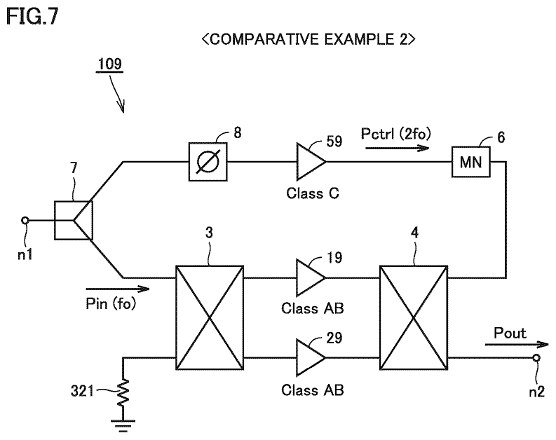

FIG. 7 is a circuit block diagram showing a configuration of a power amplifier according to the second comparative example. A power amplifier 109 according to the second comparative example is different from the power amplifier 101 according to the first embodiment (see FIG. 3) in that it includes a first amplifier 19, a second amplifier 29, and a control amplifier 59 instead of the first amplifier 1, the second amplifier 2, and the control amplifier 5. In the second comparative example, each of the first amplifier 19 and the second amplifier 29 forming the balanced type amplifier is a Class-AB amplifier, and the control amplifier 59 is a Class-C amplifier. Such a power amplifier is described in, for example, FIG. 2 of the patent literature 1.

In the second comparative example, a harmonic control is not provided at the position shown in the first comparative example (see FIG. 6). Thus, the harmonic component included in the control signal Pctrl from the control amplifier 59 may be injected into the balanced type amplifier without being removed. However, as will be described below, there is room for improvement in the effect of improving the power efficiency of the balanced type amplifier.

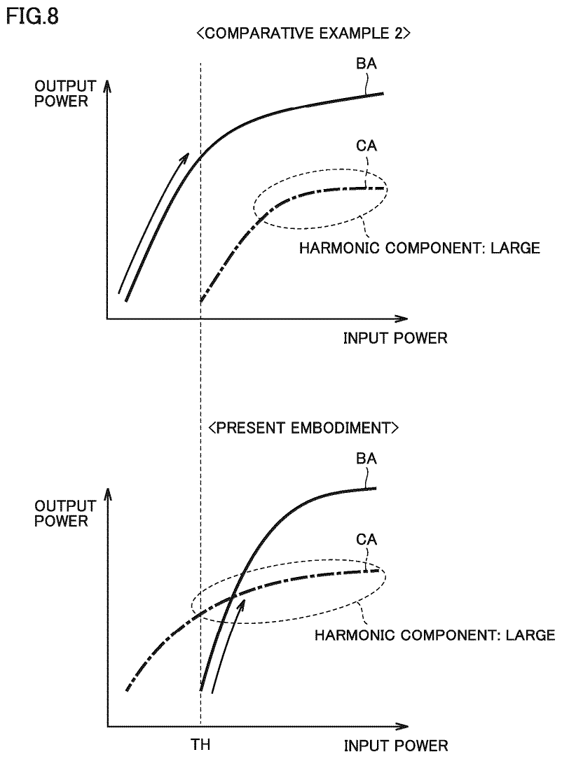

FIG. 8 is a diagram for comparing power efficiency of the power amplifier between the embodiment and the second comparative example. The horizontal axis represents the input power to the power amplifier. The vertical axis represents the output power from the power amplifier. The input/output characteristic of the balanced type amplifier (characteristic showing an increase in output power with an increase in input power) is represented by a curve with reference symbol BA. The input/output characteristic of the control amplifier is represented by a curve with reference symbol CA.

When the input power to the control amplifier is smaller than a threshold TH, the linearity of the input/output characteristic of the control amplifier is good. When the input power to the control amplifier becomes the threshold TH or more, the linearity of the control amplifier is reduced. That is, even when the input power to the control amplifier increases, the output power from the control amplifier is saturated and is less likely to increase.

When the linearity of the control amplifier is good, the control signal Pctrl output from the control amplifier does not include a harmonic component so much. In order to make the harmonic component sufficiently large, the control amplifier needs to reach a saturation state, and the distortion of the voltage waveform and the current waveform of the control signal Pctrl needs to be large. This region is shown in the figure by being surrounded by a dashed line.

In general, a load modulated balanced amplifier performs load modulation on a balanced type amplifier. In view of the original purpose of the load modulation, it is a natural premise that the balanced type amplifier is operating during the load modulation. Thus, in the second comparative example, a Class-AB balanced type amplifier that starts operating earlier than the Class-C control amplifier 59 is employed. Then, the operation of the balanced type amplifier starts at a stage where the input power to the control amplifier 59 is smaller than the threshold TH (a stage before the operation of the control amplifier 59 starts). At this time, the control signal Pctrl from the control amplifier 59 does not include a necessary amount of harmonic components. Thus, in the second comparative example, the effect of improving the power efficiency of the balanced type amplifier by the principle of the harmonic injection described above may not be sufficiently achieved.

In contrast, in the first embodiment, the control amplifier 5 is a Class-AB amplifier or a Class-B amplifier, and the balanced type amplifier BA is a Class-C amplifier. Thus, the balanced type amplifier BA remains stopped at the stage where the input power to the control amplifier 5 is smaller than the threshold TH. When the input power to the control amplifier 5 reaches the threshold TH or more, the balanced type amplifier BA starts its operation. At this time, the control signal Pctrl from the control amplifier 5 includes a large harmonic component. Thus, according to the first embodiment, it is possible to achieve a sufficient effect of improving power efficiency without delay from the start of the operation of the balanced type amplifier BA.

### Simulation

A simulation result of the power efficiency of the balanced type amplifier BA will be described. In this simulation, it is assumed that the second harmonic of frequency 2f₀ is injected into the balanced type amplifier BA with the input power Pin having a frequency of f₀. The power supplied to the first amplifier 1 and the power supplied to the second amplifier 2 are both set to 10 W. It is assumed that the distributor 3 and the combiner 4 have ideal frequency characteristics for equally distributing or combining signals over the entire frequency band.

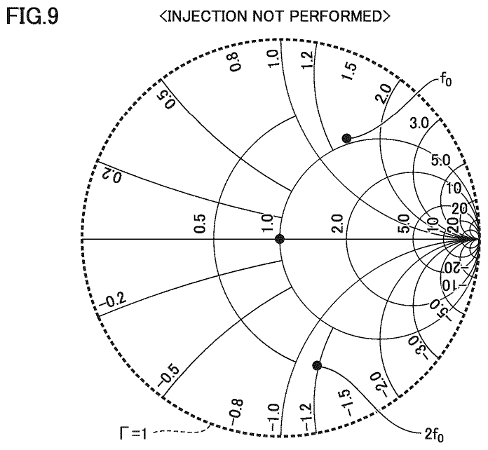

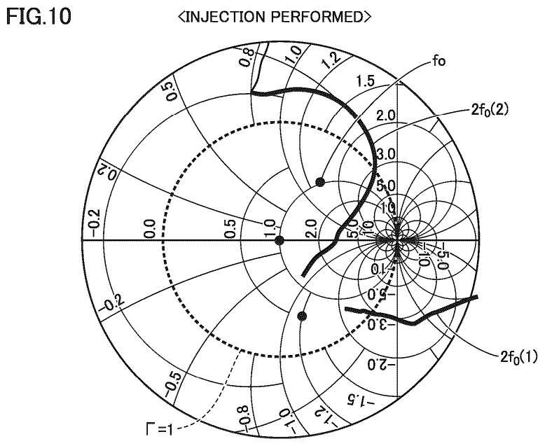

FIG. 9 is a Smith chart showing an example of a simulation result of an impedance of the balanced type amplifier when harmonic injection is not performed. FIG. 10 is a Smith chart showing an example of a simulation result of an impedance of the balanced type amplifier when harmonic injection is performed.

In each of FIGS. 9 and 10, a circle showing the reflection coefficient (ratio of the reflected wave to the incident wave) Γ=1 of the balanced type amplifier BA is shown by a dashed line. In FIG. 10, a locus showing the impedance change of the first amplifier 1 when harmonic injection is performed is represented by 2f₀(1). A locus showing the impedance change of the second amplifier 2 when harmonic injection is performed is represented by 2f₀(2). Although these two loci show different behaviors, both of them move out of the circle of the reflection coefficient Γ=1, and thus it is understood that the reflected wave becomes larger than the incident wave. This suggests that the harmonic component included in the control signal Pctrl from the control amplifier 5 has been successfully injected into the balanced type amplifier BA.

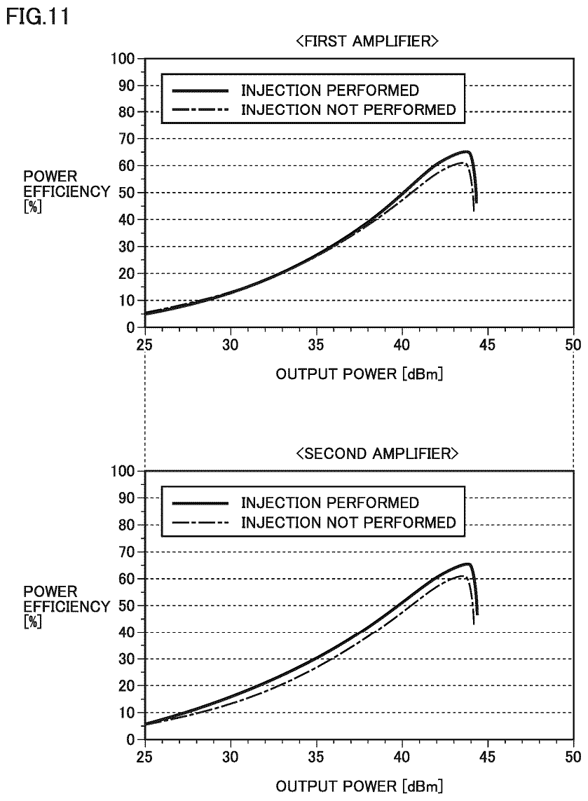

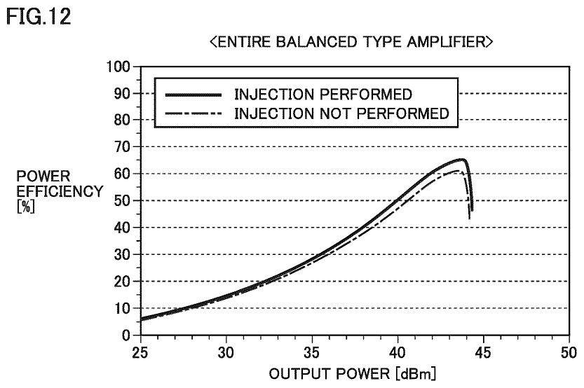

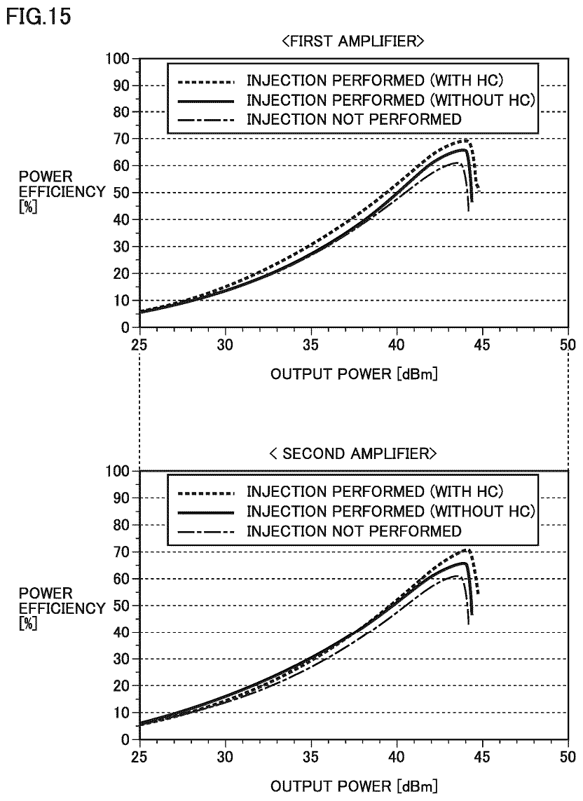

FIG. 11 is a diagram showing an example of a simulation result of power efficiency of each amplifier forming the balanced type amplifier in the first embodiment. FIG. 12 is a diagram showing an example of a simulation result of power efficiency of the entire balanced type amplifier in the first embodiment. The horizontal axis represents output power, and the vertical axis represents power efficiency. The same applies to FIG. 15 described later. The simulation result when harmonic injection is performed is indicated by a thick solid line, and the simulation result when harmonic injection is not performed is indicated by a thin one-dot dashed line.

Referring to FIG. 11, particularly in the second amplifier 2, the power efficiency is improved over the entire region of the output power including a region in which the output power is small. In the first amplifier 1, the power efficiency is improved in a region where the output power is large. As a result, as shown in FIG. 12, the power efficiency of the entire balanced type amplifier BA is improved over the entire region of the output power. The maximum value of the power efficiency when harmonic injection is not performed was 61%, whereas the maximum value of the power efficiency when harmonic injection is performed was 65%.

In the simulation shown in FIG. 11, the effect of improving the power efficiency in the second amplifier 2 was remarkable, whereas the effect of improving the power efficiency in the first amplifier 1 was not so large. However, the effect of improving the power efficiency in the second amplifier 2 is not necessarily larger than the effect of improving the power efficiency in the first amplifier 1. The magnitude of the effect may vary depending on the simulation conditions (particularly, an impedance of a circuit in a stage subsequent to an output port of the combiner 4, as will be described later).

### SUMMARY

As described above, in the first embodiment, the control amplifier 5 is a Class-AB amplifier or a Class-B amplifier, and the balanced type amplifier BA is a Class-C amplifier. Thus, as the input power increases, the operation of the control amplifier 5 is started first, and then the operation of the balanced type amplifier BA is started. When the input power to the control amplifier 5 increases and the control amplifier 5 reaches a saturation state, the harmonic component included in the control signal Pctrl increases. Thus, after the start of the operation of the balanced type amplifier BA, a sufficient harmonic component is always injected from the control amplifier 5 to the balanced type amplifier BA. This reduces the overlap (i.e., power consumption) of the voltage waveform and the current waveform of the balanced type amplifier BA from the stage where the input power to the balanced type amplifier BA is small. Thus, according to the first embodiment, the power efficiency of the balanced type amplifier BA can be improved.

In the first embodiment, since the control amplifier 5 is actively operated in a saturated state, and thus, in an actual use environment, the control amplifier 5 may deteriorate more quickly, and the reliability of the power amplifier 100, 101 may be reduced. The power amplifier 100, 101 according to the first embodiment can be said to realize load modulation that places more importance on improvement in power efficiency than on ensuring reliability.

### Second Embodiment

In a second embodiment, a configuration capable of further improving the power efficiency of the balanced type amplifier BA will be described.

### <<Configuration of Power Amplifier>>

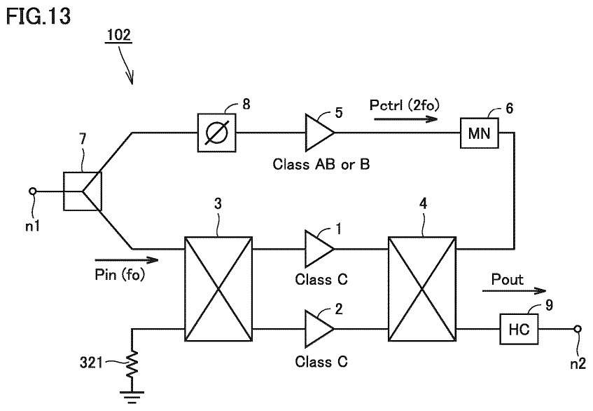

FIG. 13 is a circuit block diagram showing an example of a configuration of a power amplifier according to the second embodiment. A power amplifier 102 is different from the power amplifier 101 (see FIG. 3) in that it further includes a harmonic control 9.

A part of the control signal Pctrl injected into the isolation port of the combiner 4 leaks out from the output port of the combiner 4 to a load (not shown) via the node n2. In this case, the effect of improving the power efficiency of the balanced type amplifier BA by the harmonic injection may be weakened.

Thus, in the second embodiment, the harmonic control 9 is coupled to the output port of the combiner 4. The harmonic control 9 is configured to totally reflect the harmonic component included in the output power Pout of the balanced type amplifier BA to the output port of the combiner 4 (cause the harmonic component to undergo fixed-end reflection in the harmonic control 9). By appropriately setting parameters (such as a length of a transmission line forming a phase adjustment circuit, an inductance of a coil forming a harmonic filter, and a capacitance of a capacitor) of circuit elements included in the harmonic control 9, it is possible to return the harmonic component (including the control signal Pctrl leaking from the output port of the combiner 4) included in the output power Pout to the combiner 4 with an appropriate phase. In this way, by using the reflection (that is, the reinjection of the leaked harmonic component) of the harmonic component, the power efficiency of the balanced type amplifier BA can be further improved.

### <<Simulation>>

Two reasons why the power efficiency of the balanced type amplifier BA is further improved by the installation of the harmonic control 9 will be described in detail with reference to the following simulation results.

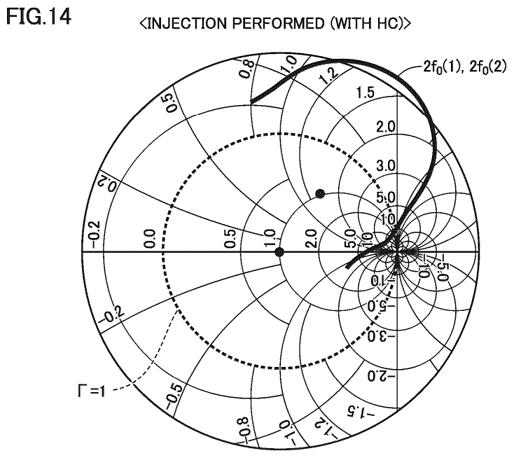

FIG. 14 is a Smith chart showing an example of a simulation result of an impedance of a balanced type amplifier when harmonic injection is performed with a harmonic control installed. This Smith chart is compared with the Smith chart (see FIG. 10) when harmonic injection is performed without installing the harmonic control 9.

First, in the first embodiment, the harmonics leaked from the output port of the combiner 4 include harmonics reflected from a circuit coupled to a stage subsequent to the output port of the combiner 4 and returning to the combiner 4, and the harmonics may be affected by the circuit of the subsequent stage. In the power amplifier 101 (see FIG. 3) according to the first embodiment, the output port of the combiner 4 is directly coupled to the circuit in the subsequent stage. This means that an impedance of the circuit in the stage subsequent to the output port of the combiner 4 is not defined. In this case, a part of the harmonics leaking from the output port of the combiner 4 is reflected at a certain point in the circuit in the subsequent stage and return to the combiner 4, while another part of harmonics is reflected at another point in the circuit in the subsequent stage and return to the combiner 4. Then, the phases of the harmonics returning to the combiner 4 vary. This can be read from the fact that the locus (see 2f₀(1)) showing the impedance change of the first amplifier 1 and the locus (see 2f₀(2)) showing the impedance change of the second amplifier 2 are separated in the Smith chart (see FIG. 10) in the first embodiment.

In the second embodiment, the harmonic control 9 is coupled to the output port of the combiner 4, and thus the impedance of the circuit in the subsequent stage of the output port of the combiner 4 is uniquely defined, and the influence of the circuit in the subsequent stage of the harmonic control 9 on the harmonic is negligibly small. Thus, the phases of the harmonics returning from the harmonic control 9 to the output port of the combiner 4 are aligned, and a standing wave of the harmonic component of the control signal Pctrl is formed between the harmonic control 9 and the output port of the combiner 4. This is supported by the fact that the impedance change of the first amplifier 1 and in the impedance change of the second amplifier 2 draw the same locus in the Smith chart shown in FIG. 14 (see 2f₀(1) and 2f₀(2)).

As described above, in the first embodiment, although the harmonics leaked from the output port of the combiner 4 include harmonics that are reflected from the circuit in the stage subsequent to the output port of the combiner 4 and return to the combiner 4, the phases of the harmonics returning to the combiner 4 are not aligned. In contrast, in the second embodiment, the harmonic control 9 is installed, and thus the phases of the harmonics returning to the combiner 4 are aligned. Thus, even when the reflection amount of the harmonic is the same between the first embodiment and the second embodiment, the effect of improving the power efficiency obtained by the reflection of the harmonic is enhanced in the second embodiment as compared with the first embodiment.

Second, in the Smith chart shown in FIG. 14, it is found that the excess amount of the locus showing the impedance change with respect to the circle showing the reflection coefficient Γ=1 is increased as compared with the Smith chart in the first embodiment (see FIG. 10). This indicates that the reflection amount of the harmonic itself has increased by installing the harmonic control 9.

FIG. 15 is a diagram showing an example of a simulation result of power efficiency of each amplifier forming the balanced type amplifier in the second embodiment. The simulation result when harmonic injection is performed with the harmonic control 9 installed is indicated by a thick dashed line. For comparison, the simulation results of the first embodiment are also shown. The thick solid line indicates a simulation result when the harmonic injection is performed without installing the harmonic control 9. The thin one-dot dashed line indicates a simulation result when the harmonic injection is not performed.

As shown in FIG. 15, according to the second embodiment, it is confirmed that the power efficiency of the balanced type amplifier BA (in this example, particularly the first amplifier 1) is improved over the entire region of the output power to the balanced type amplifier BA, as compared with the first embodiment.

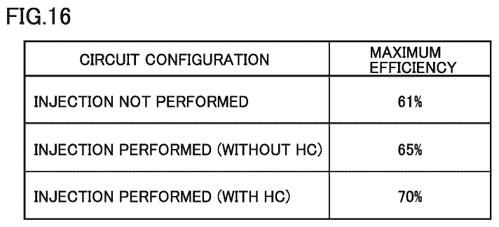

FIG. 16 is a diagram summarizing simulation results of power efficiency of the balanced power amplifiers in the first embodiment and the second embodiment. The maximum power efficiency when the harmonic injection is not performed was 61%. The maximum value of the power efficiency was 65% when the harmonic injection was performed without installing the harmonic control 9, whereas the maximum value of the power efficiency was improved to 70% by the harmonic control 9.

### SUMMARY

As described above, in the second embodiment, the control amplifier 5 is a Class-AB amplifier or a Class-B amplifier, and the balanced type amplifier BA is a Class-C amplifier, as in the first embodiment. Thus, the control signal Pctrl supplied from the control amplifier 5 to the balanced type amplifier BA always contains a sufficient harmonic component during the operation of the balanced type amplifier BA. Thus, according to the second embodiment, the power efficiency of the balanced type amplifier BA can be improved according to the principle of the harmonic injection.

In addition, in the second embodiment, the harmonic control 9 is coupled to the output port of the combiner 4. The harmonic control 9 is configured to totally reflect the harmonic component (harmonic component of the control signal Pctrl that has leaked out) included in the output power Pout from the output port of the combiner 4 to the combiner 4. This makes it possible to align the phases of the reflected waves of the harmonics and increase the amount of reflection of the harmonics. Thus, the effect of improving the power efficiency of the balanced type amplifier BA by the harmonic injection is enhanced. Thus, according to the second embodiment, the power efficiency of the balanced type amplifier BA can be further improved.

The embodiments disclosed herein are illustrative in all respects and should not be construed as limiting. The scope of the present invention is defined by the appended claims rather than the foregoing embodiments, and is intended to include all modifications within the scope and meaning equivalent to the appended claims.

What is claimed is:

1. A power amplifier comprising:
a balanced type amplifier configured to amplify an input power and including a first amplifier and a second amplifier; and
a control amplifier configured to form a load modulated balanced amplifier together with the balanced type amplifier and supply a control signal including a harmonic component of the input power to the balanced type amplifier,
wherein the control amplifier is a Class-AB amplifier or a Class-B amplifier, and
each of the first amplifier and the second amplifier is a Class-C amplifier.

2. The power amplifier according to claim 1,
wherein a transmission line for the control signal from the control amplifier to the balanced type amplifier includes no harmonic control, and
the balanced type amplifier includes no harmonic control.

3. The power amplifier according to claim 1, further comprising:
a harmonic control configured to reflect a harmonic component included in an output power of the balanced type amplifier to the balanced type amplifier.

4. The power amplifier according to claim 2, further comprising:
a harmonic control configured to reflect a harmonic component included in an output power of the balanced type amplifier to the balanced type amplifier.

5. The power amplifier according to claim 1, further comprising:
a matching network configured to match an impedance of the control amplifier with an impedance of the balanced type amplifier.

6. The power amplifier according to claim 2, further comprising:
a matching network configured to match an impedance of the control amplifier with an impedance of the balanced type amplifier.

7. The power amplifier according to claim 1,
wherein the balanced type amplifier further includes
a distributor configured to distribute the input power to the first amplifier and the second amplifier, and
a combiner configured to combine a power amplified by the first amplifier with a power amplified by the second amplifier,
wherein the distributor is a directional coupler with a phase difference of 90°, and
the distributor includes
a first port configured to receive the input power,
a second port to which a terminator is coupled,
a third port coupled to an input node of the first amplifier, and
a fourth port coupled to an input node of the second amplifier, and
wherein the combiner is a directional coupler with a phase difference of 90°, and
the combiner includes
a fifth port coupled to an output node of the first amplifier,
a sixth port coupled to an output node of the second amplifier,
a seventh port configured to receive the control signal, and
an eighth port configured to output the combined power.

8. The power amplifier according to claim 7,
wherein a transmission line between the control amplifier and the seventh port includes no harmonic control, and
the balanced type amplifier includes no harmonic control between the output node of the first amplifier and the fifth port, and includes no harmonic control between the output node of the second amplifier and the sixth port.

9. The power amplifier according to claim 7, further comprising:
a harmonic control coupled to the eighth port.

10. The power amplifier according to claim 8, further comprising:
a harmonic control coupled to the eighth port.

11. The power amplifier according to claim 7, further comprising:
a matching network coupled between the control amplifier and the seventh port.

12. The power amplifier according to claim 8, further comprising:
a matching network coupled between the control amplifier and the seventh port.

13. The power amplifier according to claim 1, further comprising:
a divider configured to divide an original signal to provide a part of the original signal to the balanced type amplifier as the input power and another part of the original signal to the control amplifier.

14. A power amplifier comprising:
a first amplifier and a second amplifier that each form a part of a balanced type amplifier configured to amplify an input power; and
a control amplifier configured to form a load modulated balanced amplifier together with the balanced type amplifier and supply a control signal including a harmonic component of the input power to the balanced type amplifier,
wherein the control amplifier is a Class-AB amplifier or a Class-B amplifier, and
each of the first amplifier and the second amplifier is a Class-C amplifier.
